(19) United States
(12) Patent Application Publication
(10) Pub. No.: US 2025/0191942 A1
(43) Pub. Date: Jun. 12, 2025

(54) SUBSTRATE PROCESSING APPARATUS

(71) Applicant: YEST CO., LTD., Pyeongtaek-si (KR)

(72) Inventors: Young Joon Ham, Pyeongtaek-si (KR); Jeong Eui Kim, Incheon (KR); Yong Hwan Kwon, Yongin-si (KR); Jin Seok Lee, Pyeongtaek-si (KR); Jong Hwan Baek, Pyeongtaek-si (KR); Byung Wook Hwang, Anseong-si (KR); Yeon Min Mo, Pyeongtaek-si (KR)

(21) Appl. No.: 18/824,593

(22) Filed: Sep. 4, 2024

(30) Foreign Application Priority Data
Dec. 8, 2023 (KR) 10-2023-0177357

(51) Int. Cl. H01L 21/67

(52) U.S. Cl. CPC H01L 21/6719; H01L 21/67109

(57) ABSTRACT

A substrate processing apparatus includes a chamber, a chamber door configured to open or close a chamber opening, an outer chamber configured to surround the chamber, in which the outer chamber includes an outer chamber upper surface, an outer chamber side surface, and an outer chamber base on an opposite side of the outer chamber upper surface and configured to seal between a chamber side surface and the outer chamber side surface, in which the outer chamber upper surface, the outer chamber side surface, and the outer chamber base form a sealed space between the outer chamber and the chamber.

### CROSS-REFERENCE TO RELATED APPLICATIONS

This application claims the priority benefit of Korean Patent Application No. 10-2023-0177357, filed on Dec. 8, 2023, in the Korean Intellectual Property Office, the entire disclosure of which is incorporated herein by reference for all purposes.

### FIELD OF THE DISCLOSURE

One or more embodiments relate to a substrate processing apparatus.

### BACKGROUND

High-pressure heat treatment of a semiconductor wafer is not only essential for manufacturing a static random-access memory (SRAM) chip by 45 nanometers (nm) process technology, which is next-generation semiconductor technology, but is also effective in increasing the driving speed and lifespan for various conventional chips. This is original technology developed in Korea and expected to play an important role in pioneering overseas markets.

As prior patents related to heat treatment of a semiconductor wafer, Korean Patent Application Publication No. 2011-0049397 ([0003] Prior Patent 1), Korean Patent Application Publication No. 2013-0110014 (Prior Patent 2), etc. are known.

Prior Patent 1 discloses forming a first oxide film on a semiconductor substrate, forming a silicon nitride film on the first oxide film, converting the silicon nitride film into a silicon-rich silicon nitride film by performing a high-pressure hydrogen heat treatment process, and sequentially forming a second oxide film and polysilicon on the silicon-rich silicon nitride film. Accordingly, the effect of preventing contamination of a low-pressure chemical vapor deposition (LPCVD) reactor and a wafer due to a change in gas partial pressure is expected.

Prior Patent 2 discloses calculating the weight of each layer from a target film thickness of an input D-poly film and a-Si film, calculating activation energy of a laminated film based on the calculated weight and the activation energy, creating a laminated film model based on a relationship with a temperature of each zone, calculating the optimum temperature for each zone to set the optimum temperature as a temperature of each zone, and forming the laminated film on a semiconductor wafer by controlling pressure and flow rate. Accordingly, the effect of easily adjusting heat treatment to an object to be processed is expected.

### SUMMARY

Embodiments provide a substrate processing apparatus that may effectively seal a space where a heat treatment process is performed on a substrate including a semiconductor.

Embodiments provide a substrate processing apparatus that may efficiently and stably implement a sealed structure in a heat treatment space.

According to an aspect, there is provided a substrate processing apparatus for performing heat treatment on a substrate, the substrate processing apparatus including a chamber including a chamber opening through which the substrate enters or exits, a chamber upper surface on an opposite side of the chamber opening, and a chamber side surface between the chamber opening and the chamber upper surface, wherein the chamber upper surface and the chamber side surface form a heat treatment space in which the substrate is accommodated, a chamber door configured to open or close the chamber opening, and an outer chamber configured to surround the chamber, in which the outer chamber includes an outer chamber side surface spaced apart outwardly from the chamber side surface, an outer chamber side surface spaced apart outwardly from the chamber side surface, and an outer chamber base on an opposite side of the outer chamber upper surface and configured to seal between the chamber side surface and the outer chamber side surface, in which the outer chamber upper surface, the outer chamber side surface, and the outer chamber base form a sealed space between the outer chamber and the chamber.

Additional aspects of embodiments will be set forth in part in the description which follows and, in part, will be apparent from the description, or may be learned by practice of the disclosure.

According to embodiments, a substrate processing apparatus may effectively seal a space where a heat treatment process is performed on a substrate.

According to embodiments, a substrate processing apparatus may allow a sealed structure of a heat treatment space to remain stable.

### BRIEF DESCRIPTION OF THE DRAWINGS

FIG. 1 is a diagram illustrating a structure of a substrate processing apparatus, according to an embodiment;

FIG. 2 is a detailed diagram illustrating a chamber door of the substrate processing apparatus, according to an embodiment; and

FIG. 3 is a diagram illustrating an operating status of the substrate processing apparatus, according to an embodiment.

### DETAILED DESCRIPTION

Hereinafter, embodiments will be described in detail with reference to the accompanying drawings. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

In addition, terms such as first, second, A, B, (a), (b), and the like may be used to describe components of the embodiments. These terms are used only for the purpose of discriminating one component from another component, and the nature, the sequences, or the orders of the components are not limited by the terms. It should be noted that if one component is described as being “connected,” “coupled” or “joined” to another component, the former may be directly “connected,” “coupled,” and “joined” to the latter or “connected”, “coupled”, and “joined” to the latter via another component.

The same name may be used to describe an element included in the embodiments described above and an element having a common function. Unless otherwise mentioned, the descriptions on the embodiments may be applicable to the following embodiments and thus, duplicated descriptions will be omitted for conciseness.

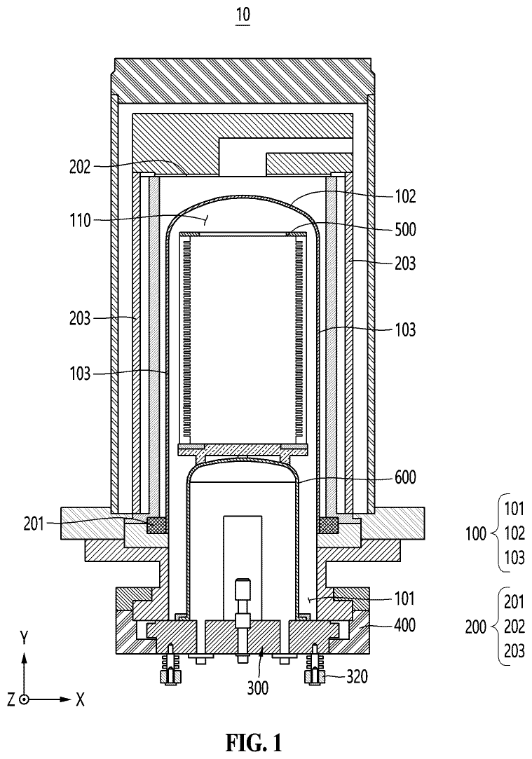

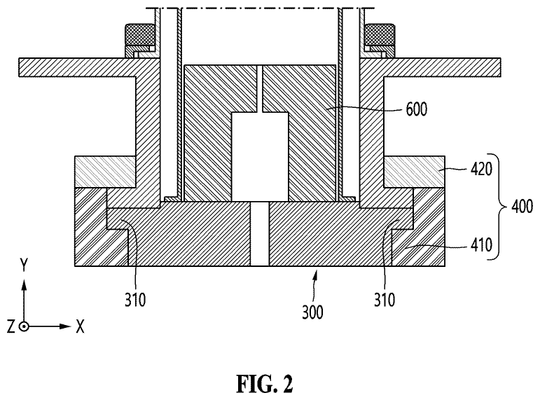

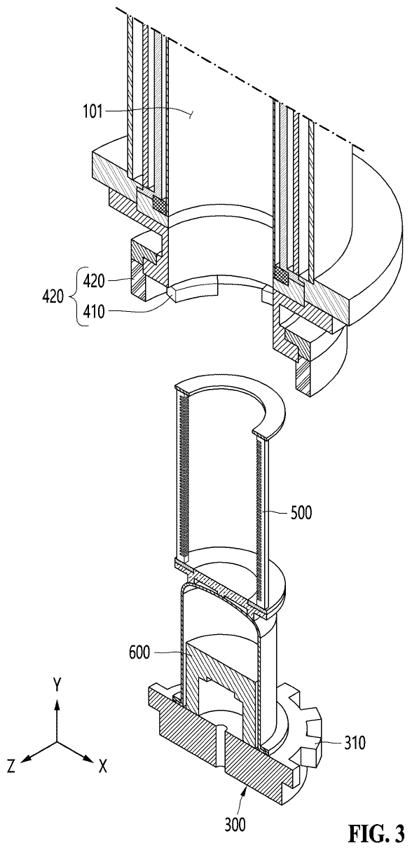

FIG. 1 is a diagram illustrating a structure of a substrate processing apparatus 10, according to an embodiment. FIG. 2 is a detailed diagram illustrating a chamber door 300 of the substrate processing apparatus 10, according to an embodiment. FIG. 3 is a diagram illustrating an operating status of the substrate processing apparatus 10, according to an embodiment.

Referring to FIGS. 1 to 3, the substrate processing apparatus 10 according to an embodiment may include a chamber 100, an outer chamber 200, and the chamber door 300.

In an embodiment, the chamber 100 may include a chamber opening 101 through which a substrate enters or exits, a chamber upper surface 102 on the opposite side of the chamber opening 101, and a chamber side surface 103 between the chamber opening 101 and the chamber upper surface 102.

The chamber 100 may include a heat treatment space 110 defined by the chamber opening 101, the chamber upper surface 102, and the chamber side surface 103. The substrate may be accommodated in the heat treatment space 110, and heat treatment may be performed on the substrate at the high temperature and/or high pressure in the heat treatment space 110. A heating portion that heats the chamber 100 may be disposed on the outer side of the chamber 100. An inlet or outlet for substrate processing gas (e.g., hydrogen, deuterium, etc.) communicating with the heat treatment space 110 may be formed in at least one of the chamber upper surface 102 and the chamber side surface 103 of the chamber 100.

The chamber opening 101 may be implemented as an opening through which the substrate enters or exits. For example, in FIG. 1, the chamber opening 101 may be formed in the lower portion of the chamber 100 (e.g., the side in the −Y direction of FIG. 1), and the chamber opening 101 may be closed by the chamber door 300.

In an embodiment, the chamber door 300 may be disposed on the lower portion of the chamber opening 101 (e.g., the side of the chamber opening 101 of FIG. 1 in the −Y direction). The chamber door 300 may move forward or backward to or from the chamber opening 101, and for example, when the chamber 100 and the chamber door 300 are placed perpendicular in the direction of gravity, the chamber door 300 may ascend or descend toward or from the chamber opening 101.

A substrate loader 500 and/or a lower heater 600 may be disposed on the upper side of the chamber door 300 (e.g., the side in the +Y direction of FIG. 1). For example, the lower heater 600 may be disposed between the chamber door 300 and the substrate loader 500.

The chamber door 300, the substrate loader 500, and the lower heater 600 may be integrally coupled. The chamber door 300, the substrate loader 500, and the lower heater 600 may ascend and descend together to and from the chamber opening 101.

A buffer element 320 may be provided on the lower side of the chamber door 300 (e.g., the side in the −Y direction of FIG. 1). For example, the buffer element 320 may be a spring. The buffer element 320 may increase the reliability of sealing by applying force to the chamber door 300 so that the chamber door 300 faces the heat treatment space 110 while the chamber door 300 seals the chamber opening 101. Additionally, the buffer element 320 may prevent the chamber door 300 from being damaged by colliding with another structure positioned on the lower portion of the chamber door 300 when the chamber door 300 descends.

In particular, referring to FIG. 3, as the chamber door 300 ascends toward the chamber opening 101 (e.g., as the chamber door 300 moves forward in the +Y direction of FIG. 3), the substrate loader 500 and the lower heater 600 may enter the heat treatment space 110. When the chamber door 300 completely closes the chamber opening 101, the heat treatment space 110 may be sealed, and the heat treatment process may be performed on the substrate while the substrate is accommodated in the sealed heat treatment space 110. In contrast, when the chamber door 300 descends from the chamber opening 101 (e.g., when the chamber door 300 moves backward in the −Y direction of FIG. 3), the substrate loader 500 and the lower heater 600 may exit the heat treatment space 110, and the substrate, on which the heat treatment process is completed, may move to the stage for the next process.

The chamber door 300 may ascend and descend along a guide, and the guide may include a frame extending in the vertical direction (e.g., the +/−Y direction of FIG. 3).

Referring back to FIG. 1, in an embodiment, the outer chamber 200 may include an outer chamber upper surface 202 spaced apart outwardly from the chamber upper surface 102, an outer chamber side surface 203 spaced apart outwardly from the chamber side surface 103, and an outer chamber base 201 on the opposite side of the outer chamber upper surface 202 and sealing between the chamber side surface 103 and the outer chamber side surface 203.

The outer chamber upper surface 202, the outer chamber side surface 203, and the outer chamber base 201 of the outer chamber 200 may surround the outer side of the chamber 100, and the chamber 100 may be placed in a completely sealed space by the outer chamber upper surface 202, the outer chamber side surface 203, the outer chamber base 201, and the chamber door 300. The space sealed by the outer chamber upper surface 202, the outer chamber side surface 203, the outer chamber base 201, and the chamber door 300 may be defined as an outer space, and since the outer space surrounds the chamber 100, predetermined external pressure may be applied to the outer side of the chamber 100. Here, when first pressure is applied to the heat treatment space 110, second pressure corresponding to the first pressure may be applied to the outer space, and through this, large force may not be applied to the chamber upper surface 102 and the chamber side surface 103 of the chamber 100 so that the chamber 100 may stably maintain its appearance even when high pressure is applied to the heat treatment space 110 of the chamber 100. The outer chamber 200 and the chamber door 300 may be made of a material with higher hardness and/or strength than the chamber 100.

For example, an inlet or outlet for inert gas (e.g., nitrogen, argon, etc.) flowing into the outer space may be formed in at least one of the outer chamber upper surface 202 and the outer chamber side surface 203 of the outer chamber 200. A heating portion that heats the outer space may be disposed in the outer chamber 200. Alternatively, the heating portion that heats the outer space may be disposed outside of the outer chamber 200 and adjacent to the outer chamber 200.

In an embodiment, the outer chamber base 201 may be coupled to a housing forming the outer chamber side surface 203. For example, the outer chamber base 201 may be bolt-coupled to the housing forming the outer chamber side surface 203. The rigid coupling of the outer chamber base 201 may allow the outer space to be maintained even in a high-pressure environment.

In an embodiment, the substrate processing apparatus 10 may further include a locking mechanism 400 for locking the chamber door 300.

In particular, referring to FIGS. 2 and 3, the chamber door 300 may include a first sawtooth structure 310. For example, the first sawtooth structure 310 may protrude to the outer side of the chamber door 300. For example, when the chamber opening 101 is implemented as a circular space and a body of the chamber door 300 also has a corresponding circular disk shape, the first sawtooth structure 310 may include protrusions regularly arranged from the body of the chamber door 300.

The locking mechanism 400 may include a donut-shaped rotating body 420 that rotates on the outer side of the chamber door 300 and a second sawtooth structure 410 protruding inwardly from the donut-shaped rotating body 420.

The first sawtooth structure 310 and the second sawtooth structure 410 may overlap each other at positions where the first sawtooth structure 310 and the second sawtooth structure 410 are placed above and below each other (e.g., at positions the first sawtooth structure 310 and the second sawtooth structure 410 are placed in the +/−Y direction of FIG. 2).

The donut-shaped rotating body 420 may be positioned on the lower portion of the outer chamber base 201 and may rotate around the Y-axis of FIG. 3. The second sawtooth structure 410 may also be rotated by the rotation of the donut-shaped rotating body 420.

In a state in which the chamber door 300 does not seal the chamber opening 101, the first sawtooth structure 310 and the second sawtooth structure 410 may be placed in a position where the first sawtooth structure 310 and the second sawtooth structure 410 do not overlap each other in the vertical direction. For example, when viewed in the Y-axis direction of FIG. 2 or 3, the first sawtooth structure 310 and the second sawtooth structure 410 may not overlap each other.

When the chamber door 300 ascends toward the chamber opening 101 and seals the chamber opening 101, the donut-shaped rotating body 420 may rotate, and the second sawtooth structure 410 may also rotate along therewith. The donut-shaped rotating body 420 may rotate until at least a portion of the second sawtooth structure 410 overlaps the first sawtooth structure 310. For example, when viewed in the Y-axis direction of FIG. 2 or 3, at least a portion of the first sawtooth structure 310 and at least a portion of the second sawtooth structure 410 may overlap each other.

Due to the overlap of the first sawtooth structure 310 and the second sawtooth structure 410, the chamber door 300 may stably maintain its position without departing from a position where the chamber opening 101 is sealed, and through this, the heat treatment space 110 may be stably sealed.

The substrate processing apparatus 10 according to an embodiment may effectively seal the heat treatment space 110 in which the heat treatment process is performed on the substrate, and the sealing of the heat treatment space 110 may be stably maintained during heat treatment of the substrate.

The substrate processing apparatus 10 according to an embodiment may perform heat treatment on the substrate. The substrate processing apparatus 10 may include the chamber 100 including the chamber opening 101 through which the substrate enters or exits, the chamber upper surface 102 on the opposite side of the chamber opening 101, and the chamber side surface 103 between the chamber opening 101 and the chamber upper surface 102, wherein the chamber upper surface 102 and the chamber side surface 103 may form the heat treatment space 110 in which the substrate is accommodated, the chamber door 300 configured to open or close the chamber opening 101, and the outer chamber 200 configured to surround the chamber 100. The outer chamber 200 may include the outer chamber upper surface 202 spaced apart outwardly from the chamber upper surface 102, the outer chamber side surface 203 spaced apart outwardly from the chamber side surface 103, and the outer chamber base 201 configured to seal between the chamber side surface 103 and the outer chamber side surface 203 on the opposite side of the outer chamber upper surface 202. The outer chamber upper surface 202, the outer chamber side surface 203, and the outer chamber base 201 may form a sealed space between the outer chamber 200 and the chamber 100.

In an embodiment, the heat treatment space 110 may be sealed by the chamber upper surface 102, the chamber side surface 103, and the chamber door 300.

In an embodiment, the substrate processing apparatus 10 may further include the locking mechanism 400 for locking the chamber door 300.

In an embodiment, the chamber door 300 may include the first sawtooth structure 310 protruding outwardly, and the locking mechanism 400 may include the donut-shaped rotating body 420 that rotates on the outer side of the chamber door 300 and the second sawtooth structure 410 protruding inwardly from the donut-shaped rotating body 420. The first sawtooth structure 310 and the second sawtooth structure 410 may overlap each other.

In an embodiment, the substrate processing apparatus 10 may further include the substrate loader 500 disposed on the chamber door 300 and on which the substrate is loaded. The lower heater 600 may be provided between the chamber door 300 and the substrate loader 500.

The chamber door 300, the substrate loader 500, and the lower heater 600 may integrally ascend or descend to or from the heat treatment space 110.

In an embodiment, the buffer element 320 may be provided on the lower surface of the chamber door 300.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order, and/or if components in a described system, architecture, device, or circuit are combined in a different manner, or replaced or supplemented by other components or their equivalents.

Therefore, other implementations, other embodiments, and equivalents to the claims are also within the scope of the following claims.

1. A substrate processing apparatus for performing heat treatment on a substrate, the substrate processing apparatus comprising:
a chamber comprising a chamber opening through which the substrate enters or exits, a chamber upper surface on an opposite side of the chamber opening, and a chamber side surface between the chamber opening and the chamber upper surface, wherein the chamber upper surface and the chamber side surface form a heat treatment space in which the substrate is accommodated;
a chamber door configured to open or close the chamber opening; and
an outer chamber configured to surround the chamber,
wherein the outer chamber comprises:
an outer chamber upper surface spaced apart outwardly from the chamber upper surface;
an outer chamber side surface spaced apart outwardly from the chamber side surface; and
an outer chamber base on an opposite side of the outer chamber upper surface and configured to seal between the chamber side surface and the outer chamber side surface,
wherein the outer chamber upper surface, the outer chamber side surface, and the outer chamber base form a sealed space between the outer chamber and the chamber.

2. The substrate processing apparatus of claim 1, wherein the heat treatment space is sealed by the chamber upper surface, the chamber side surface, and the chamber door.

3. The substrate processing apparatus of claim 1, further comprising:
a locking mechanism for locking the chamber door.

4. The substrate processing apparatus of claim 3, wherein the chamber door comprises a first sawtooth structure protruding outwardly,
wherein the locking mechanism comprises:
a donut-shaped rotating body that rotates on an outer side of the chamber door; and
a second sawtooth structure protruding inwardly from the rotating body,
wherein the first sawtooth structure and the second sawtooth structure are capable of overlapping each other.

5. The substrate processing apparatus of claim 1, further comprising:
a substrate loader disposed on the chamber door and on which the substrate is loaded.

6. The substrate processing apparatus of claim 5, wherein a lower heater is provided between the chamber door and the substrate loader.

7. The substrate processing apparatus of claim 6, wherein the chamber door, the substrate loader, and the lower heater ascend or descend to or from the heat treatment space integrally.

8. The substrate processing apparatus of claim 7, wherein a buffer element is provided on a lower surface of the chamber door.
